(19) United States
(12) Patent Application Publication
(10) Pub. No.: US 2024/0324332 A1
(43) Pub. Date: Sep. 26, 2024

(54) DISPLAY SUBSTRATE AND DISPLAY DEVICE

(71) Applicants: Chengdu BOE Optoelectronics Technology Co., Ltd., Chengdu, Sichuan Province (CN); BOE Technology Group Co., Ltd., Beijing (CN)

(72) Inventors: Jianghua LIU, Beijing (CN); Jun YAN, Beijing (CN); Benlian WANG, Beijing (CN); Yue LONG, Beijing (CN)

(21) Appl. No.: 18/023,947

(22) PCT Filed: May 24, 2022
(86) PCT No.: PCT/CN2022/094765

§ 371 Date: Jun. 10, 2024

(51) Int. Cl. H10K 59/131; G06F 3/041; H10K 59/40; H10K 59/80

(52) U.S. Cl. CPC H10K 59/131; G06F 3/0412; H10K 59/40; H10K 59/873; G06F 2203/04111

(57) ABSTRACT

A display substrate and a display device. The display substrate includes a base substrate, at least two first metal layers insulated from each other, at least two barrier dams and at least one second metal layer are sequentially arranged on the base substrate, and the base substrate includes a display region and a bezel region on at least one side of the display region. In the bezel region, the at least two barrier dams are arranged around the display region, and a first groove is provided between adjacent barrier dams; each first metal layer includes a plurality of first leads, a second groove is provided between adjacent first leads, and orthographic projections of at least some of the second grooves overlap orthographic projections of the first grooves; and the second metal layer includes a plurality of first signal wires.

### CROSS REFERENCE TO RELATED APPLICATIONS

The present disclosure is a national phase entry under 35 U.S.C § 371 of International Application No. PCT/CN2022/094765, filed May 24, 2022, and entitled “DISPLAY SUBSTRATE AND DISPLAY DEVICE”.

### FIELD

The present disclosure relates to the field of display, and particularly to a display substrate and a display device.

### BACKGROUND

In recent years, an organic light-emitting display (OLED) has attracted increasing attention as a novel flat-panel display. Owing to its excellent properties of active light emission, high light emission brightness, high resolution, a wide visual angle, a fast response speed, a small thickness, low energy consumption, flexibility, a wide use temperature range, a simple structure and manufacture process, etc., the organic light-emitting display has a broad application prospect.

### SUMMARY

Solutions of a display substrate and a display device provided in the present disclosure are as follows.

In an aspect, embodiments of the present disclosure provide a display substrate. The display substrate includes:
a base substrate, where the base substrate includes: a display region and a bezel region located on at least one side of the display region;
at least two barrier dams arranged around the display region in the bezel region, where a first groove is provided between two adjacent barrier dams;
at least two first metal layers located between a layer where the barrier dams are located and the base substrate, where a first insulation layer is arranged between two adjacent first metal layers; and each first metal layer includes a plurality of first leads located in the bezel region, a second groove is provided between two adjacent first leads, and orthographic projections of at least some of the second grooves on the base substrate overlap orthographic projections of the first grooves on the base substrate; and
at least one second metal layer located at a side of the layer where the barrier dams are located away from the base substrate; where the second metal layer includes a plurality of first signal wires located in the bezel region, the plurality of first signal wires of the at least one second metal layer includes first trace portions extending in a first direction, the first direction intersects an extension direction of the barrier dams in the bezel region located on the same side as the first trace portions, an orthographic projection of the first trace portion on the base substrate spans an overlapping region of the orthographic projection of the first groove and the orthographic projection of the second groove, and in the same second metal layer, a ratio of a line distance between two adjacent first trace portions to a line width of the first trace portion is greater than or equal to 1 and less than or equal to 4.

In some embodiments, in the above display substrate provided in the embodiments of the present disclosure, the at least one second metal layer includes a bridge metal layer, and a touch electrode layer located at a side of the bridge metal layer away from the layer where the barrier dams are located, and a second insulation layer is arranged between the bridge metal layer and the touch electrode layer.

In some embodiments, in the above display substrate provided in the embodiments of the present disclosure, at least some of the first trace portions are only located at the touch electrode layer.

In some embodiments, in the above display substrate provided in the embodiments of the present disclosure, all the first trace portions are only located at the touch electrode layer.

In some embodiments, in the above display substrate provided in the embodiments of the present disclosure, the bridge metal layer and the touch electrode layer both include the first trace portions, the first trace portions of the bridge metal layer and the first trace portions of the touch electrode layer are alternately arranged in a second direction, and the second direction is an extension direction of the barrier dams in the bezel region located at the same side as the first trace portions.

In some embodiments, in the above display substrate provided in the embodiments of the present disclosure, at least some of the first trace portions are only located at the bridge metal layer.

In some embodiments, in the above display substrate provided in the embodiments of the present disclosure, all the first trace portions are only located at the bridge metal layer.

In some embodiments, in the above display substrate provided in the embodiments of the present disclosure, the bridge metal layer and the touch electrode layer both include the first trace portions, and the first trace portions of the bridge metal layer are electrically connected with the first trace portions of the touch electrode layer in a one-to-one correspondence manner.

In some embodiments, in the above display substrate provided in the embodiments of the present disclosure, the first signal wires further include second trace portions in the bezel region, the second trace portions are electrically connected with the first trace portions, and orthographic projections of the second trace portions on the base substrate are located at a side of orthographic projections of the at least two barrier dams on the base substrate away from the display region.

In some embodiments, in the above display substrate provided in the embodiments of the present disclosure, the second trace portions are located at the bridge metal layer and the touch electrode layer, the second insulation layer includes a plurality of first via holes, and the second trace portions of the bridge metal layer are electrically connected with the second trace portions of the touch electrode layer in a one-to-one correspondence manner through the plurality of first via holes.

In some embodiments, in the above display substrate provided in the embodiments of the present disclosure, the first signal wires further include third trace portions in the bezel region, the third trace portions are electrically connected with the first trace portions, and orthographic projections of the third trace portions on the base substrate are located at a side of the orthographic projections of the at least two barrier dams on the base substrate close to the display region.

In some embodiments, in the above display substrate provided in the embodiments of the present disclosure, the third trace portions are located at the bridge metal layer and the touch electrode layer, the second insulation layer includes a plurality of second via holes, and the third trace portions of the bridge metal layer are electrically connected with the third trace portions of the touch electrode layer in a one-to-one correspondence manner through the plurality of second via holes.

In some embodiments, in the above display substrate provided in the embodiments of the present disclosure, the bridge metal layer and the touch electrode layer each include grounding wires located in the bezel region, and the grounding wires are located at a side of the plurality of first signal wires away from the display region;
at least some of the grounding wires include grounding portions arranged on a same layer as the first trace portions side by side, and a length of the grounding portion in the first direction is substantially the same as a length of the first trace portion in the first direction; and
the second insulation layer includes a plurality of third via holes, and outside the grounding portions, the grounding wires of the touch electrode layer are electrically connected with the grounding wires of the bridge metal layer through the plurality of third via holes.

In some embodiments, in the above display substrate provided in the embodiments of the present disclosure, the bridge metal layer and the touch electrode layer each include a plurality of second signal wires located in the bezel region, each second signal wire includes a fourth trace portion located in the bezel region, and an orthographic projection of the fourth trace portion on the base substrate is located between the orthographic projections of the at least two barrier dams on the base substrate and the display region.

In some embodiments, in the above display substrate provided in the embodiments of the present disclosure, the second insulation layer includes a plurality of fourth via holes, and the fourth trace portions of the bridge metal layer are electrically connected with the fourth trace portions of the touch electrode layer in a one-to-one correspondence manner through the plurality of fourth via holes.

In some embodiments, in the above display substrate provided in the embodiments of the present disclosure, each second signal wire includes a fifth trace portion extending in the first direction in the bezel region, the fifth trace portion and the fourth trace portion are integrally arranged, and an orthographic projection of the fifth trace portion on the base substrate spans the orthographic projections of the at least two barrier dams on the base substrate.

In some embodiments, in the above display substrate provided in the embodiments of the present disclosure, each first metal layer further includes a plurality of second leads located in the bezel region, and orthographic projections of the second leads of different first metal layers on the base substrate are staggered; a third groove is provided between two adjacent second leads of the same first metal layer, and orthographic projections of at least some of the third grooves on the base substrate overlap the orthographic projections of the first grooves on the base substrate; and an orthographic projection of the fifth trace portion on the base substrate spans an overlapping region of the orthographic projection of the first groove and the orthographic projection of the third groove.

In some embodiments, the above display substrate provided in the embodiments of the present disclosure further includes a plurality of data signal wires located between the at least two first metal layers and the layer where the barrier dams are located in the display region, and the plurality of data signal wires are electrically connected with the plurality of second leads.

In some embodiments, in the above display substrate provided in the embodiments of the present disclosure, the first trace portion includes a first trace sub-portion and a second trace sub-portion that are integrally arranged, an orthographic projection of the first trace sub-portion on the base substrate is located within the orthographic projections of the barrier dams on the base substrate, an orthographic projection of the second trace sub-portion on the base substrate does not overlap the orthographic projections of the barrier dams on the base substrate, and a line width of the first trace sub-portion is less than a line width of the second trace sub-portion.

In some embodiments, in the above display substrate provided in the embodiments of the present disclosure, the line width of the first trace portion is greater than or equal to 8 μm and less than or equal to 15 μm, and the line distance between two adjacent first trace portions in the same second metal layer is greater than or equal to 15 μm and less than or equal to 30 μm.

In some embodiments, in the above display substrate provided in the embodiments of the present disclosure, in the first direction, a distance between the orthographic projection of the first trace portion on the base substrate and the orthographic projections of the at least two barrier dams on the base substrate is greater than or equal to 40 μm and less than or equal to 60 μm.

In some embodiments, in the above display substrate provided in the embodiments of the present disclosure, the plurality of first signal wires include a plurality of touch signal wires, and guard lines on a side of the touch signal wires away from the display region.

In some embodiments, the above display substrate provided in the embodiments of the present disclosure further includes a gate drive circuit located in the bezel region, where the gate drive circuit is electrically connected with the plurality of first leads.

In the other aspect, an embodiment of the present disclosure provides a display device. The display device includes the above display substrate provided in the embodiments of the present disclosure.

### BRIEF DESCRIPTION OF THE DRAWINGS

FIG. 1 is a schematic structural diagram of a display substrate according to an embodiment of the present disclosure.

FIG. 2 is an enlarged schematic structural diagram of region M in FIG. 1.

FIG. 3 is an enlarged schematic structural diagram of region N in FIG. 2.

FIG. 4 is a schematic structural diagram of a first metal layer in FIG. 3.

FIG. 5 is a schematic structural diagram of a bridge metal layer in FIG. 3.

FIG. 6 is a schematic structural diagram of a touch electrode layer in FIG. 3.

FIG. 7 is a sectional view of the region N in FIG. 2 in direction X.

FIG. 8 is a sectional view of the region N in FIG. 2 in direction Y.

FIG. 9 is another enlarged schematic structural diagram of the region N in FIG. 2.

FIG. 10 is a schematic structural diagram of a bridge metal layer in FIG. 9.

FIG. 11 is a schematic structural diagram of a touch electrode layer in FIG. 9.

FIG. 12 is another enlarged schematic structural diagram of the region N in FIG. 2.

FIG. 13 is a schematic structural diagram of a bridge metal layer in FIG. 12.

FIG. 14 is a schematic structural diagram of a touch electrode layer in FIG. 12.

FIG. 15 is another enlarged schematic structural diagram of the region N in FIG. 2.

FIG. 16 is another schematic structural diagram of the first metal layer in the region N in FIG. 2.

FIG. 17 is a sectional view of region K in FIG. 2 in direction X.

FIG. 18 is a sectional view of the region K in FIG. 2 in the direction Y.

FIG. 19 is a schematic structural diagram of a first metal layer in the region K in FIG. 2.

FIG. 20 is a schematic structural diagram of a display region contained in a display substrate according to an embodiment of the present disclosure.

### DETAILED DESCRIPTION OF THE EMBODIMENTS

In order to make objectives, technical solutions and advantages of embodiments of the present disclosure clearer, the technical solutions of the present disclosure will be clearly and completely described below in combination with accompanying drawings in the embodiments of the present disclosure. It should be noted that sizes and shapes of all figures in accompanying drawings do not reflect true scale and are merely intended to illustrate contents of the present disclosure. Moreover, from beginning to end, identical or similar reference numerals denote identical or similar elements or elements having identical or similar functions. In order to keep the following descriptions of embodiments of the present disclosure clear and concise, the present disclosure omits detailed descriptions of known functions and known components.

Unless otherwise defined, technical terms or scientific terms used herein should have the ordinary meanings understood by those of ordinary skill in the art to which the present disclosure belongs. “First”, “second” and other similar words used in the description and the claims of the present disclosure do not indicate any order, quantity or importance, but are merely used to distinguish between different components. “Include”, “contain” or other similar words mean that an element or object appearing before the word contains elements or objects listed after the word and equivalents thereof, without excluding other elements or objects. Terms “inner”, “outer”, “upon”, “lower”, etc. are merely used to indicate relative positional relations, and when the absolute position of a described object changes, the relative position may change accordingly.

With the rapid development of an active matrix organic light-emitting diode (AMOLED) display technology, the development of AMOLED products has entered an era of full screens and narrow bezels. In order to bring better user experiences, it is inevitable to develop the AMOLED products towards a full screen, a narrow bezel, high resolution, flexible wear, foldability and so on in the future. In order to achieve lightness and thinness to adapt to foldable and rollable products in the future, a flexible multi-layer on cell (FMLOC) technology emerges. An FMLOC process is to manufacture a metal grid electrode layer on a thin film encapsulation (TFE) of a display module to achieve a touch function, such that an external touch structure is not required, thereby reducing a screen thickness.

Two layers of metal are generally used for manufacture through the FMLOC process, one is a metal mesh layer as a touch electrode layer, and the other one is a bridge metal layer. The touch electrode layer includes transverse and longitudinal metal grids, which are touch drive (Tx) metal grids and touch sensing (Rx) metal grids respectively, where the Rx metal grids are interconnected, and the Tx metal grids are connected with each other through the bridge metal layer; or the Tx metal grids are interconnected, and the Rx metal grids are connected with each other through the bridge metal layer. Moreover, barrier dams located in a bezel region, and a plurality of touch signal wires electrically connected with the touch drive metal grids and the touch sensing metal grids respectively are arranged in an FMOC product. The barrier dams are arranged around the display region to block external water vapor or oxygen from entering the display region. One barrier dam may be arranged in order to further improve a narrow bezel effect; under the condition of low requirement on a narrow bezel, a plurality of barrier dams may be arranged; and in some embodiments, one barrier dam may be divided into at least two barrier sub-dams in a lower bezel region. At least some of the touch signal wires are required to span all the barrier dams in the lower bezel region to be electrically connected with a drive integrated circuit (IC).

However, some traces (for example, traces connected with a gate drive circuit) are arranged below the layer where the barrier dams are located, these traces are of single-layer or double-layer wiring structures, and orthographic projections of at least some of the grooves between these traces overlap orthographic projections of grooves between the two barrier dams, such that the groove between the two barrier dams is deep. In a process of manufacturing touch signal wires on the layer where the barrier dams are located, metal residue of the bridge metal layer is likely to be generated at the groove between the two barrier dams, and adjacent touch signal wires are short-circuited via the metal residue, thereby affecting touch performance.

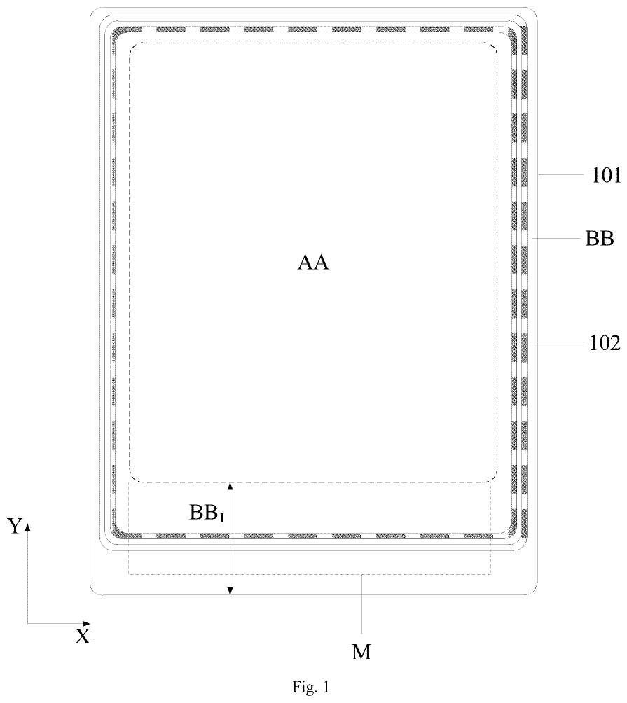

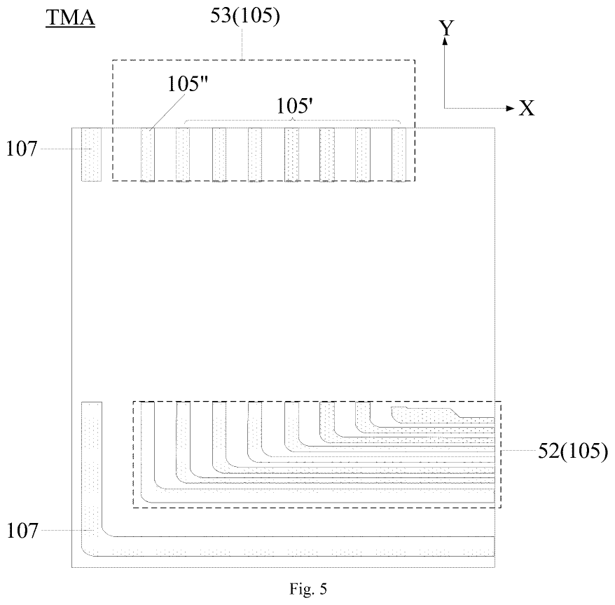

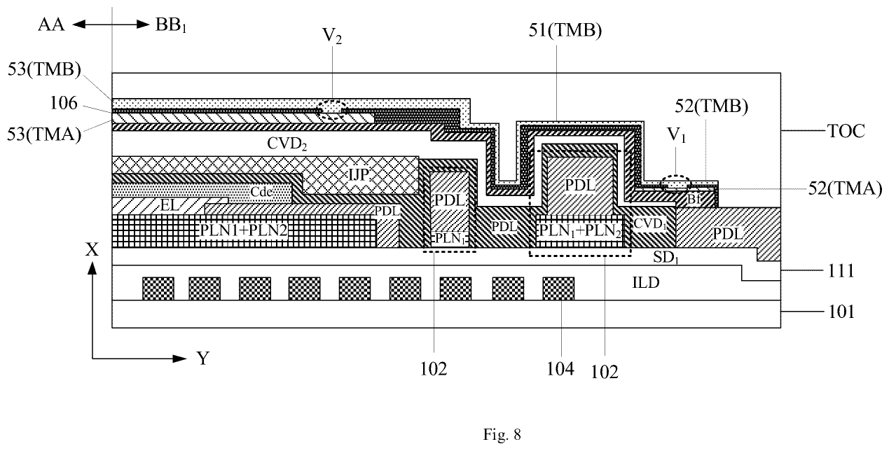

In order to solve the above technical problems in the related art, embodiments of the present disclosure provide a display substrate. As shown in FIGS. 1-8, the display substrate includes:
a base substrate 101, where the base substrate 101 includes: a display region AA, and a bezel region BB located on at least one side of the display region AA;
at least two barrier dams 102 arranged around the display region AA in the bezel region BB, where a first groove C₁ is provided between two adjacent barrier dams 102; optionally, the bezel region BB surrounds the display region AA and includes a first bezel region BB₁ for binding a drive chip; each barrier dam 102 may surround the display region AA within the bezel region BB; or a plurality of barrier dams 102 are arranged in the first bezel region BB₁ at intervals, and at least some of the barrier dams 102 are combined into one barrier dam 102 in the bezel region BB outside the first bezel region BB₁;
at least two first metal layers (for example, a first gate metal layer G₁ and a second gate metal layer G₂) located between the layer where the barrier dams 102 are located and the base substrate 101, where a first insulation layer 103 is arranged between two adjacent first metal layers (for example, the first gate metal layer G₁ and the second gate metal layer G₂); and each first metal layer (for example, the first gate metal layer G₁ and the second gate metal layer G₂) includes a plurality of first leads 104 located in the bezel region BB, optionally, orthographic projections of the first leads 104 of the at least two first metal layers (for example, the first gate metal layer G₁ and the second gate metal layer G₂) on the base substrate 101 overlap each other, a second groove C₂ is provided between two adjacent first leads 104, and the orthographic projections of at least some of the second grooves C₂ on the base substrate 101 overlap the orthographic projections of the first grooves C₁ on the base substrate 101; and
at least one second metal layer (for example, a bridge metal layer TMA and a touch electrode layer TMB) located at a side of the layer where the barrier dams 102 are located away from the base substrate 101; where the second metal layer (for example, the bridge metal layer TMA and the touch electrode layer TMB) includes a plurality of first signal wires 105 located in the bezel region BB, optionally, the plurality of first signal wires 105 may include a plurality of touch signal wires 105′ (for example, touch drive wires Tx and touch sensing wires Rx), and guard lines 105″ on a side of the plurality of touch signal lines 105′ (for example, the touch drive wires Tx and the touch sensing wires Rx) away from the display region AA; and the first signal wire 105 of the at least one second metal layer (for example, the bridge metal layer TMA and the touch electrode layer TMB) includes first trace portions 51 extending in a first direction Y, the first direction Y intersects an extension direction X of the barrier dams 102, an orthographic projection of the first trace portion 51 on the base substrate 101 spans an overlapping region of an orthographic projection of the first groove C₁ and an orthographic projection of the second groove C₂, and in the same second metal layer (for example, the bridge metal layer TMA and the touch electrode layer TMB), a ratio of a line distance between two adjacent first trace portions 51 to a line width of the first trace portion 51 is greater than or equal to 1 and less than or equal to 4.

In the above display substrate provided in the embodiments of the present disclosure, by setting the ratio of the line distance between two adjacent first trace portions 51 in the same second metal layer (for example, the bridge metal layer TMA and the touch electrode layer TMB) and the line width of the first trace portion 51 to be greater than or equal to 1 and less than or equal to 4, it is ensured that the line distance between two adjacent first trace portions 51 is great, thereby reducing the risk that the adjacent first trace portions 51 both are in contact with metal residue, and effectively overcoming a defect of a short circuit of the adjacent first signal wires 105 including the first trace portions 51.

In addition, since many first trace portions 51 are arranged, if the line distance between the adjacent first trace portions 51 is great, a large wiring space is required to arrange all the first trace portions 51, which is not conducive to realization of a narrow bezel design. Therefore, it is required to reasonably set the line distance between the adjacent first trace portions 51. In the present disclosure, by setting the ratio of the line distance between two adjacent first trace portions 51 in the same second metal layer (such as the bridge metal layer TMA and the touch electrode layer TMB) to the line width of the first trace portion 51 is greater than or equal to 1 and less than or equal to 4, it is ensured that a wiring space required by all the first trace portions 51 is small, which is conducive to realization of a narrow bezel.

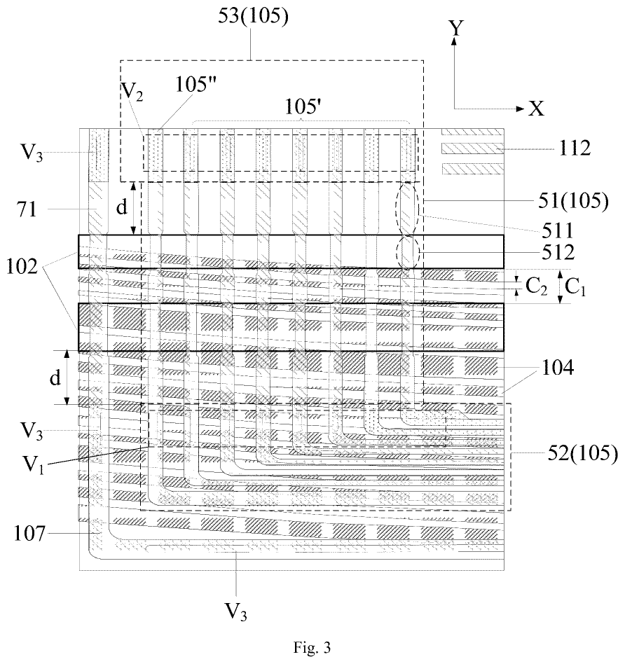

In some embodiments, in the above display substrate provided in the embodiments of the present disclosure, as shown in FIGS. 3-8, the at least one second metal layer may include a bridge metal layer TMA, and a touch electrode layer TMB located a side of the bridge metal layer TMA away from the layer where the barrier dams 102 are located, and a second insulation layer 106 is arranged between the bridge metal layer TMA and the touch electrode layer TMB. That is, the second metal layer in the present disclosure is designed through an FMOC technology, so as to achieve touch control on the basis of a mutual-capacitance principle. Certainly, in some embodiments, the second metal layer in the present disclosure may only include a single transparent electric conduction layer, and touch control is achieved on the basis of a self-capacitance principle. In the present disclosure, at least one second metal layer including a bridge metal layer TMA and a touch electrode layer TMB is taken as an example for description.

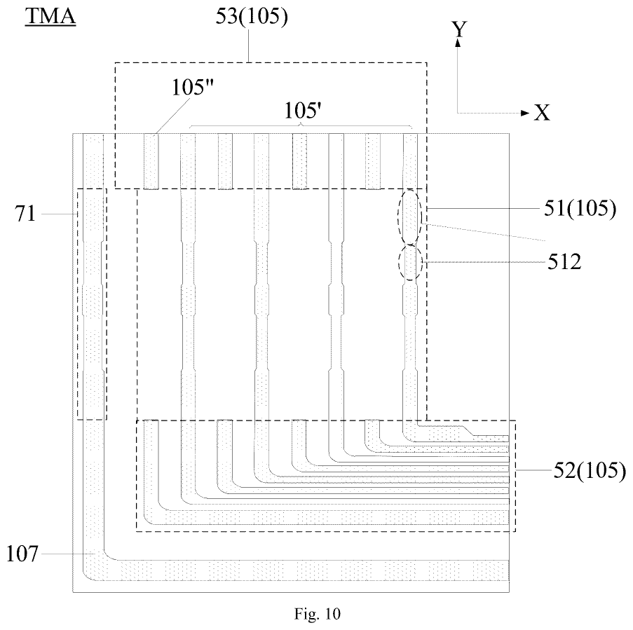

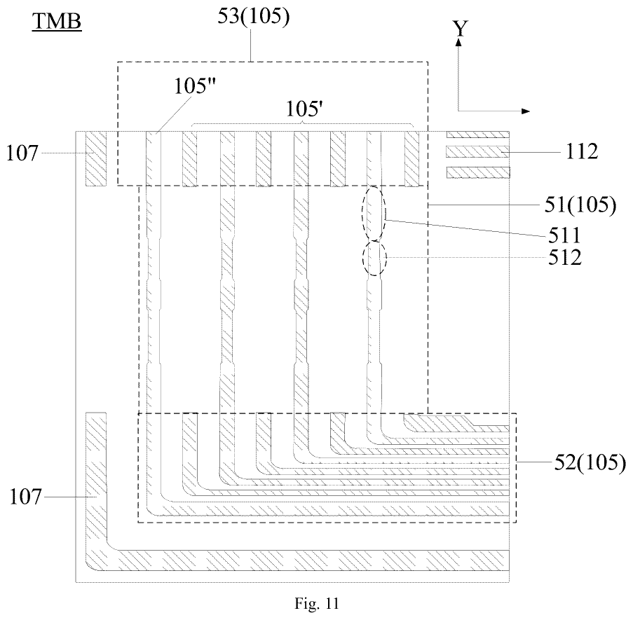

In some embodiments, as shown in FIGS. 3, 5, 6 and 9-11, in the above display substrate provided in the embodiments of the present disclosure, at least some of the first trace portions 51 are only located in the touch electrode layer TMB. Since a second insulation layer 106 is arranged between the bridge metal layer TMA and the touch electrode layer TMB, the second insulation layer 106 may fill up the first groove C₁ between the barrier dams 102 to a certain extent, such that a groove depth of the touch electrode layer TMB at the first groove C₁ is less than a groove depth of the bridge metal layer TMA at the first groove C₁. In view of this, a possibility of generating metal residue by the first trace portion 51 at the first groove C₁ is extremely small or even zero. Therefore, in the situation that the first trace portions 51 are arranged in the touch electrode layer TMB, a short circuit of the adjacent first trace portions 51 may be effectively avoided.

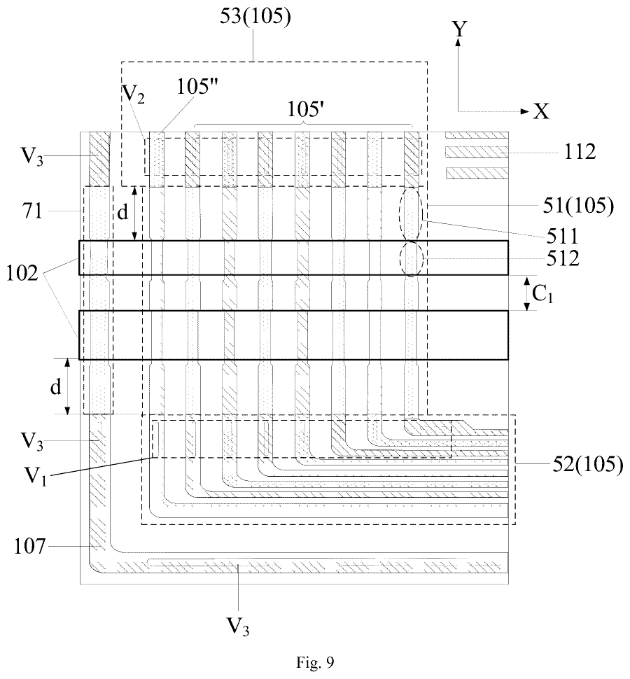

In some embodiments, in the above display substrate provided in the embodiments of the present disclosure, as shown in FIGS. 3, 5 and 6, the entire first trace portions 51 may be arranged only in the touch electrode layer TMB, so as to avoid a short circuit of the adjacent first trace portions 51. Certainly, in some embodiments, as shown in FIGS. 9-11, the bridge metal layer TMA and the touch electrode layer TMB may include the first trace portions 51, and the first trace portions 51 of the bridge metal layer TMA and the first trace portions 51 of the touch electrode layer TMB are alternately arranged in a second direction, and the second direction is an extension direction X of the barrier dams 102 located in the bezel region BB on the same side as the first trace portions 51. It is easy to understand that within a range of process variation, in the situation that the first trace portions 51 of the bridge metal layer TMA and the first trace portions 51 of the touch electrode layer TMB are alternately arranged in the extension direction X of the barrier dams, a line distance of two adjacent first trace portions 51 in the same layer is equal to the sum of twice a line distance of two adjacent first trace portions 51 in the extension direction X of the barrier dams 102 in different layers and a line width of one first trace portion 51. Therefore, the line distance between two adjacent first trace portions 51 in the same layer is great, to further avoid a short circuit between two adjacent first trace portions 51 in the same layer.

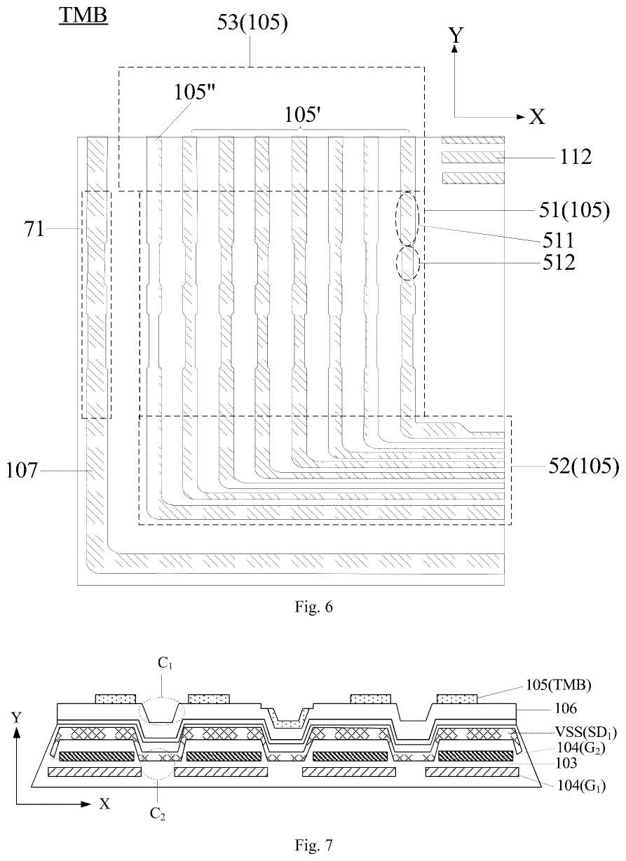

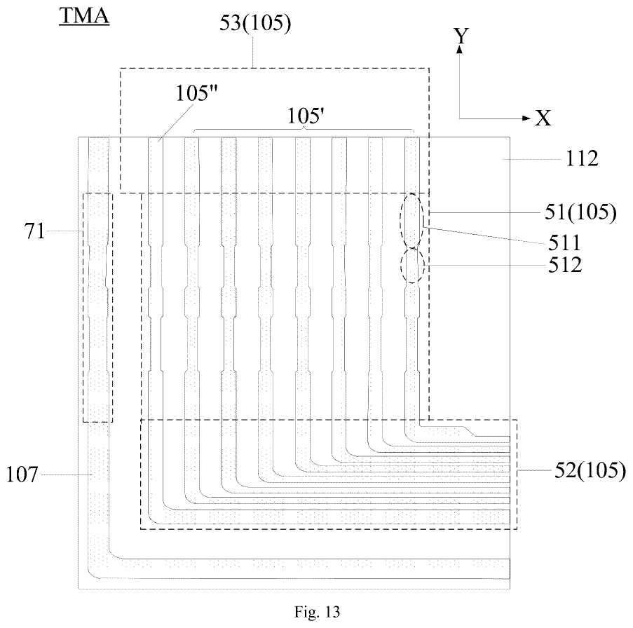

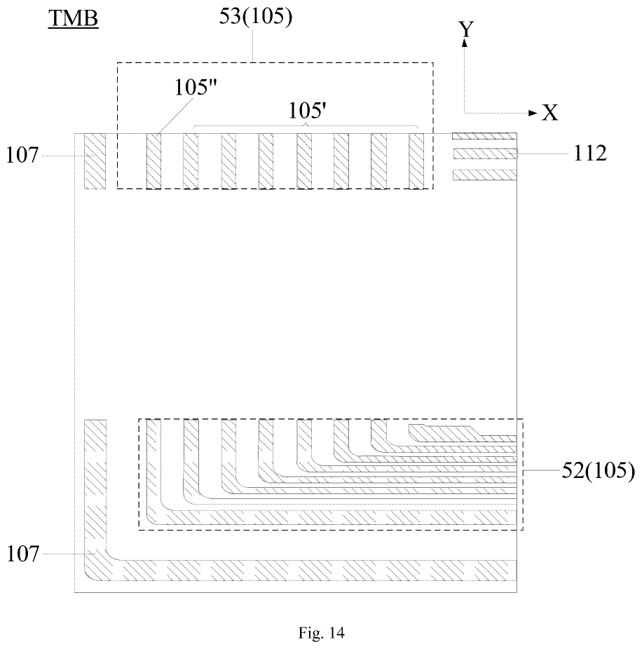

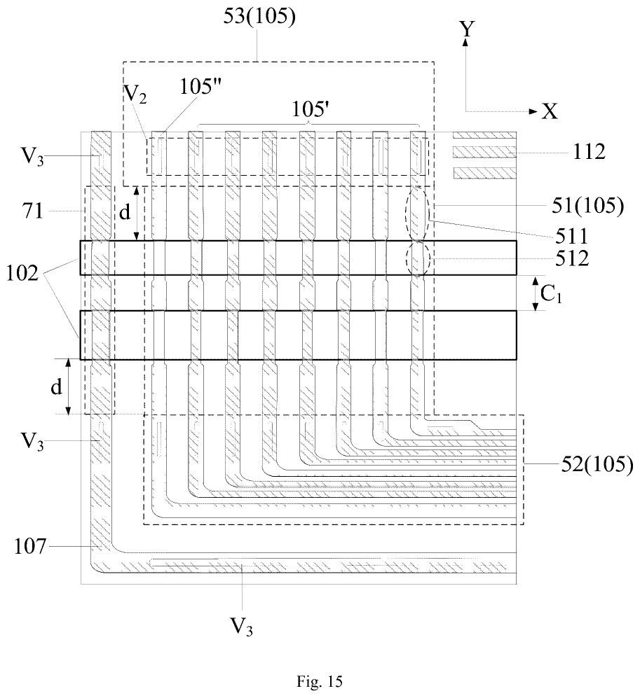

In some embodiments, in the above display substrate provided in the embodiments of the present disclosure, as shown in FIGS. 6 and 12-15, at least some of the first trace portions 51 are only located on the bridge metal layer TMA. Although a relatively great groove depth of the bridge metal layer TMA at the first groove C₁ may result in residue of the bridge metal layer TMA at the first groove C₁, in the present disclosure, the line distance between two adjacent first trace portions 51 in the same layer is increased. Therefore, the risk that the adjacent first trace portions 51 both are in contact with metal residue may be effectively reduced, thereby effectively overcoming a defect of a short circuit of the adjacent first signal wires 105 including the first trace portions 51.

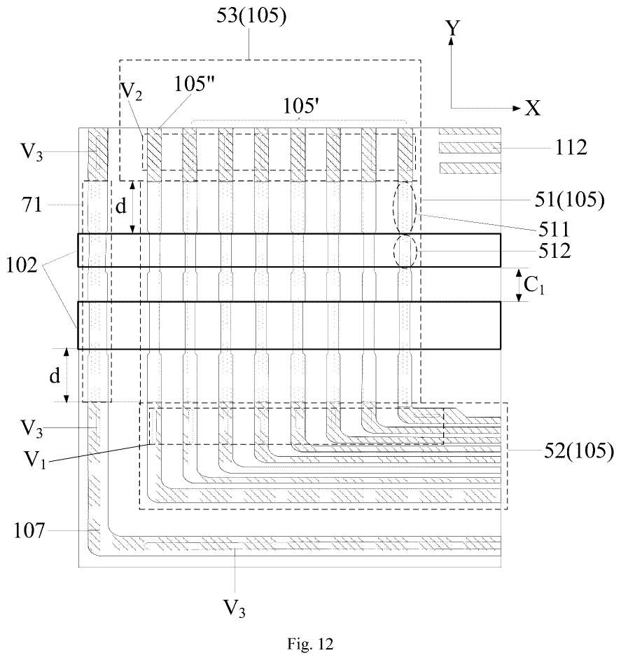

In some embodiments, in the above display substrate provided in the embodiments of the present disclosure, as shown in FIGS. 12-14, the entire first trace portion 51 is only located at the bridge metal layer TMA; or as shown in FIGS. 6, 13 and 15, the bridge metal layer TMA and the touch electrode layer TMB both include the first trace portions 51, the first trace portions 51 of the bridge metal layer TMA are electrically connected with the first trace portions 51 of the touch electrode layer TMB in a one-to-one correspondence manner, and the orthographic projection of the first trace portion 51 of the bridge metal layer TMA on the base substrate 101 substantially coincides with the orthographic projection of the corresponding first trace portion 51 of the touch electrode layer TMB on the base substrate 101, that is, the orthographic projections of the two first trace portions just coincide with each other or are within an error range caused by factors such as manufacture and measurement. By electrically connecting the first trace portions 51 of the bridge metal layer TMA with the first trace portions 51 of the touch electrode layer TMB in a one-to-one correspondence manner, that is, by setting the first signal wire 105 to attain a double-layer wiring structure, resistance of the first signal wires 105 may be reduced, and continuity of the first signal wires 105 may be ensured through the first trace portions 51 on the other layer after the first trace portions 51 on one layer are partially broken, thereby improving reliability of the first signal wires 105.

In some embodiments, in the above display substrate provided in the embodiments of the present disclosure, as shown in FIGS. 6, 11 and 13, the first trace portion 51 includes a first trace sub-portion 511 and a second trace sub-portion 512 that are integrally arranged, an orthographic projection of the first trace sub-portion 511 on the base substrate 101 is located within an orthographic projection of the barrier dam 102 on the base substrate 101, an orthographic projection of the second trace sub-portion 512 on the base substrate 101 and an orthographic projection of the barrier dam 102 on the base substrate 101 do not overlap each other, and a line width of the first trace sub-portion 511 is less than a line width of the second trace sub-portion 512. By setting the first trace portions 51 to be trace structures having widths that alternately change at positions spanning the barrier dams 102, a distance between every two adjacent first trace portions 51 at the positions spanning the barrier dams 102 may be increased, an occurrence rate of a short circuit may be reduced, and a touch yield may be improved.

In some embodiments, in the above display substrate provided in the embodiments of the present disclosure, the line width of the first trace portion 51 may be greater than or equal to 8 μm and less than or equal to 15 μm, for example, the line width of the first trace portion 51 may be 8 μm, 9 μm, 10 μm, 11 μm, 12 μm, 13 μm, 14 μm or 15 μm. Accordingly, in order to satisfy that a ratio of the line distance to the line width is 1-4, the line distance between two adjacent first trace portions 51 in the same second metal layer (for example, the bridge metal layer TMA and the touch electrode layer TMB) may be greater than or equal to 15 μm and less than or equal to 30 μm, for example, the line distance between two adjacent first trace portions 51 in the same second metal layer (for example, the bridge metal layer TMA and the touch electrode layer TMB) is 15 μm, 20 μm, 25 μm or 30 μm.

It should be noted that the line width of the same first signal wire 105 may be non-uniform due to the limitation of a wiring space. For example, in the situation of a sufficient wiring space, the line width of the first signal wire 105 may be relatively greater, and in the situation of a limited wiring space, the line width of the first signal wire 105 may be relatively less. Optionally, the line width of the first signal wire 105 may be 3 μm-15 μm. Optionally, during specific implementation, the line width of the first signal wire 105 at different positions may be designed according to actual requirements. For example, in the above first trace portion 51, the line width of the first trace sub-portion 511 overlapping the barrier dam 102 is less than the line width of the second trace sub-portion 512 not overlapping the barrier dam 102, and the line width of the first trace sub-portion 511 and the line width of the second trace sub-portion 512 may both be 8 μm-15 μm.

In some embodiments, in the above display substrate provided in the embodiments of the present disclosure, as shown in FIG. 3, in order to satisfy exposure accuracy, in the first direction Y, the distance d between an edge of the orthographic projection of the first trace portion 51 on the base substrate 101 and an edge of the orthographic projections of the at least two barrier dams 102 on the base substrate 101 may be greater than or equal to 40 μm and less than or equal to 60 μm, and the edge of the orthographic projection of the first trace portion 51 and the edge of the orthographic projections of the at least two barrier dams 102 are on a same side, for example, the distance d is a distance between the upper edge of the orthographic projection of the first trace portion 51 on the base substrate 101 and the upper edge of the orthographic projections of the at least two barrier dams 102 on the base substrate 101. For, example, the distance d is 40 μm, 45 μm, 50 μm, 55 μm or 60 μm.

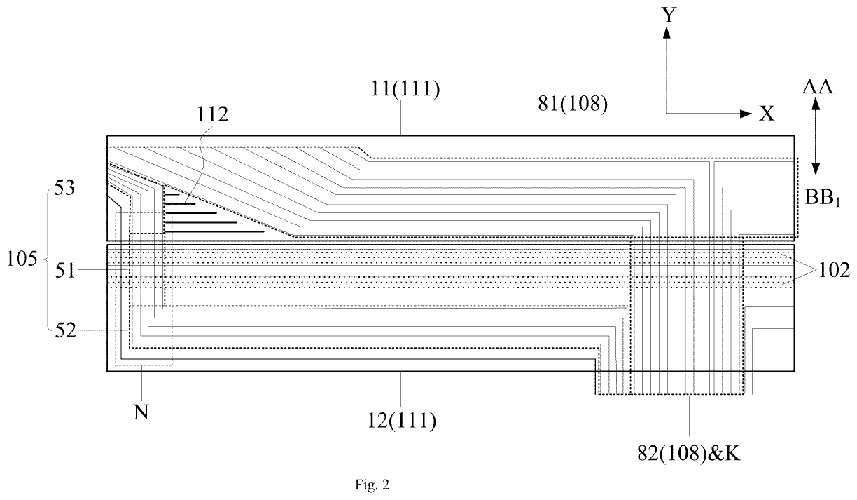

In some embodiments, in the above display substrate provided in the embodiments of the present disclosure, as shown in FIGS. 2, 3, 5 and 6, the first signal wires 105 may further include second trace portions 52 in the bezel region BB, and the second trace portions 52 are electrically connected with the first trace portions 51, and in the situation that the first signal wires 105 include the first trace portions 51 and the second trace portions 52 that are located at the same layer, the first trace portions 51 and the second trace portions 52 of the same first signal wire 105 may be integrally arranged. Optionally, the orthographic projections of the second trace portions 52 on the base substrate 101 are located a side of the orthographic projections of the at least two barrier dams 102 on the base substrate 101 away from the display region AA, so as to reasonably utilize a space outside the at least two barrier dams 102, thereby effectively reducing a width of the bezel region BB within the barrier dam 102, which is conducive to realization of a product requirement for a narrower bezel design.

In some embodiments, in the above display substrate provided in the embodiments of the present disclosure, as shown in FIGS. 3, 5 and 6, the second trace portions 52 may be located in the bridge metal layer TMA and the touch electrode layer TMB, the second insulation layer 106 includes a plurality of first via holes V₁, and the second trace portions 52 of the bridge metal layer TMA are electrically connected with the second trace portions 52 of the touch electrode layer TMB in a one-to-one correspondence manner through the plurality of first via holes V₁, such that on the side of the barrier dams 102 away from the display region AA, the first signal wire 105 has a double-layer wiring structure, which may reduce resistance of the first signal wire 105, and may improve reliability of the first signal wire 105. Optionally, the orthographic projection of the second trace portion 52 of the bridge metal layer TMA on the base substrate 101 substantially coincides with the orthographic projection of the corresponding second trace portion 52 of the touch electrode layer TMB on the base substrate 101, that is, the orthographic projections of the two second trace portions just coincide with each other or are within an error range caused by factors such as manufacture and measurement.

In some embodiments, in the above display substrate provided in the embodiments of the present disclosure, as shown in FIGS. 2, 3, 5 and 6, the first signal wires 105 may further include third trace portions 53 in the bezel region BB, and the third trace portions 53 are electrically connected with the first trace portions 51. In the situation that the first signal wire 105 includes the first trace portion 51 and the third trace portion 53 that are located at the same layer, the first trace portion 51 and the third trace portion 53 of the same first signal wire 105 may be integrally arranged. Optionally, the orthographic projection of the third trace portion 53 on the base substrate 101 is located on a side of the orthographic projection of the at least two barrier dams 102 on the base substrate 101 close to the display region AA, which is conducive to realization of an electrical connection between the first signal wire 105 (for example, a touch signal wire) and a component (for example, a touch electrode) in the display region AA.

In some embodiments, in the above display substrate provided in the embodiments of the present disclosure, as shown in FIGS. 3, 5 and 6, the third trace portions 53 are located at the bridge metal layer TMA and the touch electrode layer TMB, the second insulation layer 106 includes a plurality of second via holes V₂, and the third trace portions 53 of the bridge metal layer TMA are electrically connected with the third trace portions 53 of the touch electrode layer TMB in a one-to-one correspondence manner through the plurality of second via holes V₂, such that on the side of the barrier dams 102 close to the display region AA, the first signal wire 105 has a double-layer wiring structure. Therefore, resistance of the first signal wire 105 may be reduced, and reliability of the first signal wire 105 may be improved. Optionally, the orthographic projection of the third trace portion 53 of the bridge metal layer TMA on the base substrate 101 substantially coincides with the orthographic projection of the corresponding third trace portion 53 of the touch electrode layer TMB on the base substrate 101, that is, the orthographic projections of the two third trace portions just coincide with each other or are within an error range caused by factors such as manufacture and measurement.

In some embodiments, in the above display substrate provided in the embodiments of the present disclosure, as shown in FIGS. 3, 5, 6 and 9-15, the bridge metal layer TMA and the touch electrode layer TMB may each further include grounding wires 107 located in the bezel region BB, and the grounding wires 107 are located on a side of all the first signal wires 105 away from the display region AA. At least some of the grounding wires 107 include grounding portions 71 that are arranged on the same layer as the first trace portions 51 side by side, a length of the grounding portion 71 in the first direction Y is substantially the same as a length of the first trace portion 51 in the first direction Y, that is, the length of the grounding portion 71 and the length of the first trace portion 51 are the same or are within an error range caused by factors such as manufacture and measurement.

It can be seen from FIGS. 3, 5, 6, and 9-15 that the first trace portions 51 may be located in the bridge metal layer TMA and/or the touch electrode layer TMB. Therefore, the grounding portions 71 and the first trace portions 51 may be arranged at the same layer in the bridge metal layer TMA and/or the touch electrode layer TMB. Since a line distance between the grounding wire 107 and the first signal wire 105 is great in the related art, the probability of a short circuit between the grounding wire and the first signal wire is extremely small. Therefore, in the present disclosure, even if the grounding wire 107 of the bridge metal layer TMA and/or the touch electrode layer TMB has the grounding portions 71, no short circuit occurs between the grounding wire 107 and the first signal wire 105. In the situation that only the grounding wire 107 of the touch electrode layer TMB has the grounding portions 71, the grounding wire 107 is of a single-layer wiring structure only in the touch electrode layer TMB in a region overlapping the barrier dams 102 and the first groove C₁. Since a second insulation layer 106 is arranged between the bridge metal layer TMA and the touch electrode layer TMB, the second insulation layer 106 may fill up the first groove C₁ between the barrier dams 102 to a certain extent, and a groove depth of the touch electrode layer TMB at the first groove C₁ is less than a groove depth of the bridge metal layer TMA at the first groove C₁. In view of this, a possibility of generating metal residue by the touch electrode layer TMB at the first groove C₁ is extremely small or even zero. Therefore, in the situation that the first trace portion 51 and the grounding portion 71 are only arranged in the touch electrode layer TMB, a short circuit of the grounding wire 107 and the adjacent first signal wire 105 may be better prevented.

In some embodiments, the line width of the grounding wire 107 provided in the present disclosure is greater than or equal to 10 μm and less than or equal to 50 μm, for example, the line width of the grounding wire 107 is 10 μm, 15 μm, 20 μm, 25 μm, 30 μm, 35 μm, 40 μm, 45 μm or 50 μm. A distance between the grounding wire 107 and the adjacent first signal wire 105 is greater than or equal to 30 μm and less than or equal to 50 μm, for example, the distance between the grounding wire 107 and the adjacent first signal wire 105 is 30 μm, 35 μm, 40 μm, 45 μm or 50 μm.

In some embodiments, as shown in FIGS. 3, 5, 6, and 9-15, the second insulation layer 106 includes a plurality of third via holes V₃, and outside the grounding portions 71, the grounding wires 107 of the touch electrode layer TMB are electrically connected with the grounding wires 107 of the bridge metal layer TMA through the plurality of third via holes V₃, such that the area of the grounding wire 107 other than the grounding portion 71 is of a double-layer wiring structure, and thus the grounding wire 107 has lower resistance and better reliability.

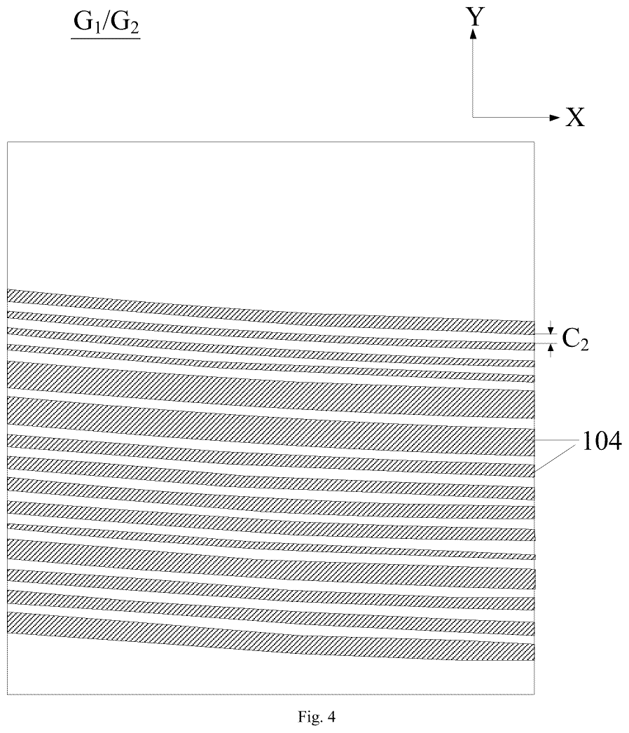

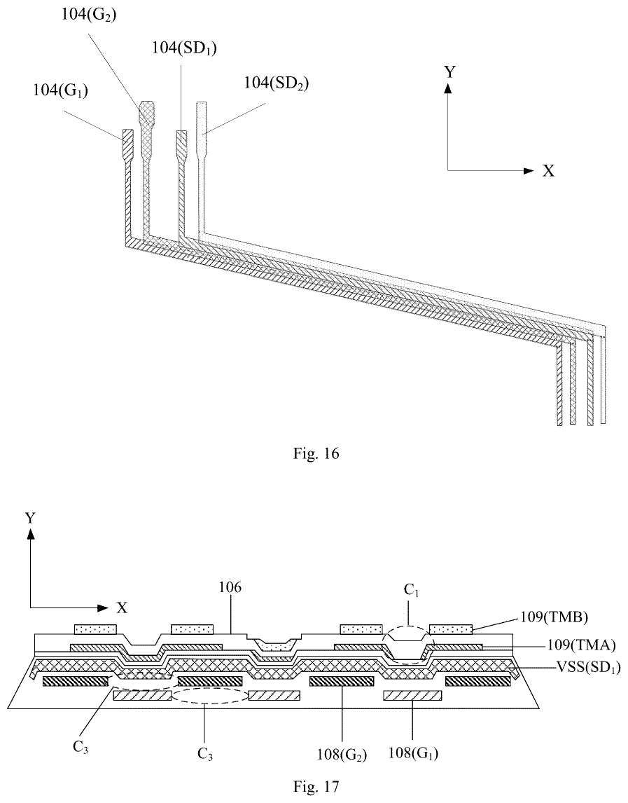

In some embodiments, in the above display substrate provided in the embodiments of the present disclosure, as shown in FIGS. 4 and 16, the at least two first metal layers may include a first gate metal layer G₁, a second gate metal layer G₂, a first source and drain metal layer SD₁, and a second source and drain metal layer SD₂. Optionally, as shown in FIG. 4, the first leads 104 of which orthographic projections overlap each other may be arranged only in the first gate metal layer G₁ and the second gate metal layer G₂, that is, the first leads 104 are only arranged in the first gate metal layer G₁ and the second gate metal layer G₂, and the orthographic projections of the first leads 104 arranged in the first gate metal layer G₁ on the base substrate 101 are overlap with the orthographic projections of the first leads 104 arranged in the second gate metal layer G₂ on the base substrate 101; or as shown in FIG. 16, the first leads 104 of which orthographic projections overlap each other may be arranged in the first gate metal layer G₁, the second gate metal layer G₂, the first source and drain metal layer SD₁ and the second source and drain metal layer SD₂.

In some embodiments, the orthographic projections of the first leads 104 of different first metal layers on the base substrate 101 may substantially coincide with, that is, the orthographic projections of the first leads coincide with each other or are within an error range caused by factors such as manufacture and measurement. For example, in FIG. 4, the orthographic projection of the first lead 104 of the first gate metal layer G₁ on the base substrate 101 coincides with the orthographic projection of the first lead 104 of the second gate metal layer G₂ on the base substrate 101. In some other embodiments, the orthographic projections of the first leads 104 of different first metal layers on the base substrate 101 may partially overlap. For example, in FIG. 16, the orthographic projection of the first lead 104 of the first gate metal layer G₁ on the base substrate 101 partially overlaps the orthographic projection of the first lead 104 of the second gate metal layer G₂ on the base substrate 101, the orthographic projection of the first lead 104 of the second gate metal layer G₂ on the base substrate 101 partially overlaps the orthographic projection of the first lead 104 of the first source and drain metal layer SD₁ on the base substrate 101, and the orthographic projection of the first lead 104 of the first source and drain metal layer SD₁ on the base substrate 101 partially overlaps the orthographic projection of the first lead 104 of the second source and drain metal layer SD₂ on the base substrate 101.

In some embodiments, the display substrate provided in the embodiments of the present disclosure may include a pixel drive circuit and a light-emitting device electrically connected with the pixel drive circuit, and the pixel drive circuit may include an oxide transistor, a low-temperature polysilicon transistor, a capacitor, etc. In this situation, the at least two first metal layers provided in the present disclosure may further include a first gate metal layer G₁, a second gate metal layer G₂, a third gate metal layer G₃, a first source and drain metal layer SD₁ and a second source and drain metal layer SD₂. A gate of the oxide transistor, a gate of the low-temperature polysilicon transistor and the capacitor may be located at the first gate metal layer G₁, the second gate metal layer G₂ and the third gate metal layer G₃, and a source and drain of the oxide transistor and a source and drain of the low-temperature polysilicon transistor may be located at the first source-drain metal layer SD₁. The second source and drain metal layer SD₂ may include an adapter electrode connecting the pixel drive circuit with the light-emitting device. Optionally, the first leads 104 in the present disclosure may be arranged in at least two of the first gate metal layer G₁, the second gate metal layer G₂, the third gate metal layer G₃, the first source and drain metal layer SD₁ and the second source and drain metal layer SD₂.

In some embodiments, in the above display substrate provided in the embodiments of the present disclosure, as shown in FIGS. 2, 17 and 18, the bridge metal layer TMA and the touch electrode layer TMB each include a plurality of second signal wires 108 (for example, touch signal wires) located in the bezel region BB, each second signal wire 108 includes a fourth trace portion 81 in the bezel region BB, and the orthographic projection of the fourth trace portion 81 on the base substrate 101 is located between the orthographic projections of the at least two barrier dams 102 on the base substrate 101 and the display region AA. Compared with the solution that the third trace portion 53 and the fourth trace portion 81 are both arranged between the barrier dams 102 and the display region AA, the present disclosure employs the solution that the fourth trace portion 81 is arranged between the barrier dams 102 and the display region AA, which may effectively ensure that a width of the bezel region BB within the barrier dams 102 is less and is conducive to realization of a narrow bezel design.

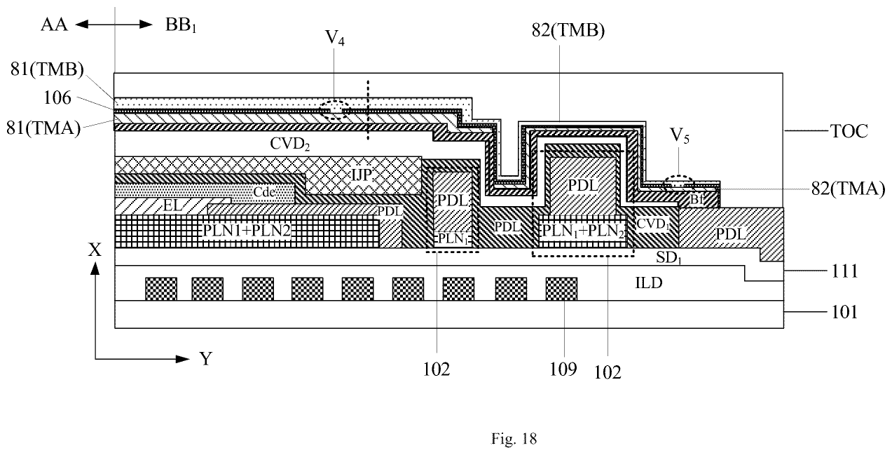

In some embodiments, in the above display substrate provided in the embodiments of the present disclosure, as shown in FIG. 18, the second insulation layer 106 includes a plurality of fourth via holes V₄, and the fourth trace portions 81 of the bridge metal layer TMA are electrically connected with the fourth trace portions 81 of the touch electrode layer TMB through the plurality of fourth via holes V₄ in a one-to-one correspondence manner, such that the second signal wire 108 has a double-layer wiring structure between the barrier dams 102 and the display region AA, thereby reducing resistance of the second signal wires 108, and improving reliability of the second signal wires 108. Optionally, the orthographic projection of the fourth trace portion 81 of the bridge metal layer TMA on the base substrate 101 may substantially coincide with the orthographic projection of the corresponding fourth trace portion 81 of the touch electrode layer TMB on the base substrate 101, that is, the orthographic projections of the two fourth trace portions just coincide with each other or are within an error range caused by factors such as manufacture and measurement.

In some embodiments, in the above display substrate provided in the embodiments of the present disclosure, as shown in FIGS. 2, 17 and 18, each second signal wire 108 may further include a fifth trace portion 82 extending in the first direction Y in the bezel region BB, the fifth trace portion 82 and the fourth trace portion 81 are integrally arranged, and the orthographic projection of the fifth trace portion 82 on the base substrate 101 spans the orthographic projection of at least two barrier dams 102 on the base substrate 101, which is conducive to realization of an electrical connection between the second signal wire 108 (for example, a touch signal wire) and a drive integrated circuit (IC) bound on a side of the barrier dams 102 away from the display region AA.

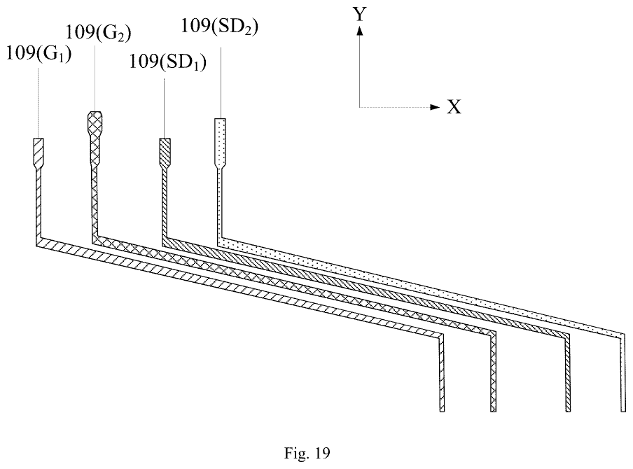

In some embodiments, in the above display substrate provided in the embodiments of the present disclosure, as shown in FIGS. 17 and 19, each first metal layer (for example, the first gate metal layer G₁ and the second gate metal layer G₂) may further include a plurality of second leads 109 located in the bezel region BB, and orthographic projections of the second leads 109 of different first metal layers (for example, the first gate metal layer G₁ and the second gate metal layer G₂) on the base substrate 101 are staggered. A third groove C₃ is provided between two adjacent second leads 109 of the same first metal layer (for example, the first gate metal layer G₁ and the second gate metal layer G₂), and the orthographic projections of at least some of the third grooves C₃ on the base substrate 101 overlap the orthographic projections of the first grooves C₁ between the barrier dams 102 on the base substrate 101. The orthographic projection of the fifth trace portion 82 on the base substrate 101 may span an overlapping region of the orthographic projection of the first groove C₁ and the orthographic projection of the third groove C₃. Since orthographic projections of the second leads 109 of the different first metal layers (for example, the first gate metal layers G₁ and the second gate metal layers G₂) on the base substrate 101 are staggered, third grooves C₃ between the second leads 109 of the different first metal layers (for example, the first gate metal layers G₁ and the second gate metal layers G₂) may staggered to a certain degree, such that an overlapping depth of the third grooves C₃ of each first metal layer is small. Even if the first groove C₁ and the third groove C₃ between the barrier dams 102 have an overlapping region, the third groove C₃ has a little influence on a depth of the first groove C₁, and in a process of manufacturing the second leads 109, there is no metal residue in the first groove C₁. In view of this, in the present disclosure, it is ensured that no short circuit occurs between the adjacent second leads 109 in the same layer.

In some embodiments, in the above display substrate provided in the embodiments of the present disclosure, as shown in FIG. 18, the second insulation layer 106 includes a plurality of fifth via holes V₅, and the fifth trace portions 82 of the bridge metal layer TMA are electrically connected with the fifth trace portions 82 of the touch electrode layer TMB through the fifth via holes V₅ in a one-to-one correspondence manner, such that the second signal wire 108 has a double-layer wiring structure on the side of the barrier dams 102 away from the display region AA, thereby reducing resistance of the second signal wires 108, and improving reliability of the second signal wires 108. Optionally, the orthographic projection of the fifth trace portion 82 of the bridge metal layer TMA on the base substrate 101 may substantially coincide with the orthographic projection of the corresponding fifth trace portion 82 of the touch electrode layer TMB on the base substrate 101, that is, the orthographic projections of the two fifth trace portions just coincide with each other or are within an error range caused by factors such as manufacture and measurement.

In some embodiments, in order to improve electrical connection performance of the double-layer wiring structure, a width of the via hole of the double-layer trace (for example, the first via hole V₁, the second via hole V₂, the third via hole V₃, the fourth via hole V₄ and the fifth via hole V₅) may be greater than or equal to 3.5 μm and less than or equal to 5 μm, and a length may be greater than or equal to 10 μm and less than or equal to 30 μm, for example, the width of the via hole is 3.5 μm, 4 μm, 4.5 μm or 5 μm, and the length of the via hole is 10 μm, 15 μm, 10 μm, 25 μm or 30 μm.

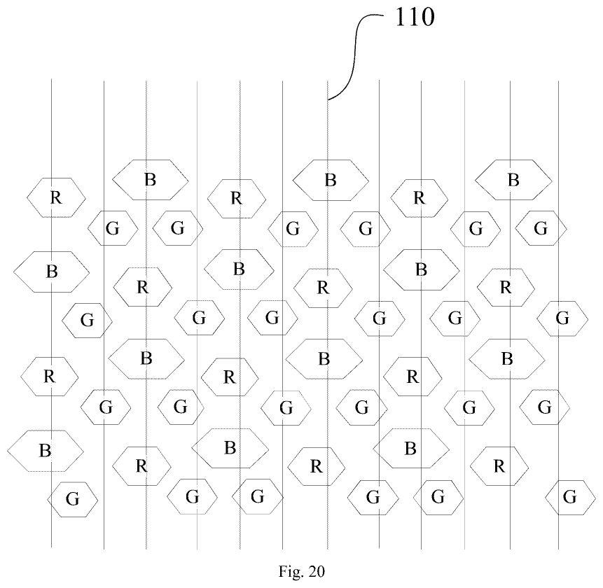

In some embodiments, in the above display substrate provided in the embodiments of the present disclosure, as shown in FIG. 20, the first source and drain metal layer SD₁ may include a plurality of data signal wires 110 located in the display region AA, and the plurality of data signal wires 110 are electrically connected with a plurality of second leads 109. Optionally, the data signal wires 110 may be electrically connected with the second leads 109 in a one-to-one correspondence manner, and one data signal wire 110 is electrically connected with one column of light-emitting devices. In some embodiments, the light-emitting device may be an organic light-emitting device (Oled), a quantum dot light-emitting device (Qled), a mini light-emitting device (Mini led), a micro light-emitting device (Micro led), etc. The light-emitting device may include a red light-emitting device R, a green light-emitting device G, a blue light-emitting device B, etc. For an arrangement mode of the light-emitting devices, reference may be made to the related art, which is not limited herein.

In some embodiments, the above display substrate provided in the embodiments of the present disclosure may further include a gate drive circuit GOA located in the bezel region BB, and the gate drive circuit GOA is electrically connected with a plurality of first leads 104. Optionally, the gate drive circuit GOA may include a plurality of shift registers arranged in cascade, and the first leads 104 may include a clock signal wire (Clk), a light emission control signal wire (EM), a reset signal wire (Rst), a reference signal wire (Vref), etc., which are not limited herein.

In some embodiments, as shown in FIGS. 2 and 8, the above display substrate provided in the embodiments of the present disclosure may further include a shielding structure 111. The shielding structure 111 is arranged around the display region AA in the bezel region BB, and the shielding structure 111 may be located between all the first metal layers (for example, the first gate metal layers G₁ and the second gate metal layers G₂) and the layer where the barrier dams 102 are located, such that the first metal layer and the second metal layer are separated by the shielding structure 111, so as to prevent the first leads 104 and the second leads 109 in the first metal layer from interfering in the first signal wires 105 and the second signal wires 108 in the second metal layer.

In some embodiments, as shown in FIG. 2, the shielding structure 111 may include a first shielding structure 11 and a second shielding structure 12, the first shielding structure 11 is located between the second shielding structure 12 and the display region AA, an orthographic projection of the first shielding structure 11 on the base substrate 101 and the orthographic projections of the barrier dams 102 on the base substrate 101 do not overlap each other, and the orthographic projection of the second shielding structure on the base substrate 101 covers the orthographic projection of the barrier dams 102 on the base substrate 101. Optionally, in order to achieve a better shielding effect, the shielding structure 111 may be connected with a fixed potential signal, for example, the first shielding structure 11 may be connected with a first level signal VDD, and the second shielding structure 12 may be connected with a second level signal VSS.

In some embodiments, as shown in FIGS. 2, 3 and 6, the touch electrode layer TMB may further include a floating wire 112, and an orthographic projection of the floating wire 112 on the base substrate 101 is located in a space delimited by the orthographic projection of the barrier dams 102 on the base substrate 101, the orthographic projection of the third trace portion 51 on the base substrate 101, and the orthographic projection of the fourth trace portion 81 on the base substrate 101. Optionally, an extension direction of the floating wire 112 is substantially the same as the extension direction X of the barrier dams 102, that is, extension directions of the floating wire and the barrier dam are parallel to each other or intersect each other within an error range caused by factors such as manufacture and measurement. By arranging the floating wire 112 in the region delimited by the barrier dams 102, the third trace portion 53, and the fourth trace portion 81, a wiring structure in the region may be closer to a structure of the surrounding trace region, thereby improving process stability and product stability. Optionally, the floating wire 112 may be located on the touch electrode layer TMB.

In some embodiments, as shown in FIGS. 8 and 18, two barrier dams 102 may be arranged in the present disclosure, one barrier dam 102 close to the display region AA may be composed of a pixel defining layer (PDL) and a second planarization layer (PLN₂), and the other barrier dam 102 away from the display region AA may be composed of a pixel defining layer (PDL), a second planarization layer (PLN₂), and a first planarization layer (PLN₁). Since the barrier dam 102 away from the display region AA has less film pattern located on the first planarization layer (PLN₁) than the barrier dam 102 close to the display region AA, a height of the barrier dam 102 away from the display region AA relative to the base substrate 101 is lower than that of the barrier dam 102 close to the display region AA relative to the base substrate 101, which may lengthen a path for external water vapor and oxygen to enter the display region AA, increase a difficulty of external water vapor and oxygen entering the display region AA, and improve a barrier capability of the barrier dams 102. Certainly, in some embodiments, the film layer structures of the two barrier dams 102 may be the same, for example, the two barrier dams 102 each are composed of the pixel defining layer (PDL) and the second planarization layer (PLN₂), or the two barrier dams 102 each are composed of the pixel defining layer (PDL), the second planarization layer (PLN₂) and the first planarization layer (PLN₁), which is not limited herein.

In some embodiments, as shown in FIGS. 8 and 18, the display substrate provided in the present disclosure may further include: an interlayer dielectric layer (ILD), a light-emitting function layer (EL), a cathode (Cde), a first inorganic encapsulation layer (CVD₁), an organic encapsulation layer (IJP), a second inorganic encapsulation layer (CVD₂), a buffer layer (Bf), a third planarization layer (TOC), etc., and the light-emitting function layer (EL) includes, but is not limited to, a hole injection layer, a hole transport layer, an electron barrier layer, a light-emitting material layer, a hole barrier layer, an electron transport layer and an electron injection layer. Other essential components of the display substrate would be understood by those of ordinary skill in the art and will not be repeated herein, and should not be regarded as a limitation of the present disclosure.

On the basis of the same inventive concept, the embodiments of the present disclosure provide a display device. The display device includes the above display substrate provided in the embodiments of the present disclosure. Since the principle of solving the problem of the display device is similar to the principle of solving the problem of the above display substrate, for implementation of the display device provided in the embodiments of the present disclosure, reference may be made to implementation of the above display substrate provided in the embodiments of the present disclosure, and repetitions will not be described.

In some embodiments, the above display device provided in the embodiments of the present disclosure may be a mobile phone, a tablet computer, a television, a monitor, a laptop, a digital photo bezel, a navigator, a smart watch, a fitness wristband, a personal digital assistant and other products or components having display functions. The display device includes but is not limited to: a radio frequency device, a network module, an audio output and input device, a sensor, a display device, a user input device, an interface device, a memory, a processor, a power supply, etc. In addition, those skilled in the art can understand that the above structure does not limit the above display device provided in the embodiments of the present disclosure. In other words, the above display device provided in the embodiments of the present disclosure can include more or less components, or a combination of some components, or different component arrangements.

Apparently, those skilled in the art can make various modifications and variations to embodiments of the present disclosure without departing from the spirit and scope of the present disclosure. In this way, if these modifications and variations of embodiments of the present disclosure fall within the scope of the claims of the present disclosure and equivalent technologies thereof, the present disclosure is further intended to include these modifications and variations.

1. A display substrate, comprising:
a base substrate, wherein the base substrate comprises: a display region and a bezel region located on at least one side of the display region;
at least two barrier dams arranged around the display region in the bezel region, wherein a first groove is provided between two adjacent barrier dams;
at least two first metal layers located between a layer where the barrier dams are located and the base substrate, wherein a first insulation layer is arranged between two adjacent first metal layers; and each first metal layer comprises a plurality of first leads located in the bezel region, a second groove is provided between two adjacent first leads, and orthographic projections of at least some of the second grooves on the base substrate overlap orthographic projections of the first grooves on the base substrate; and
at least one second metal layer located at a side of the layer where the barrier dams are located away from the base substrate; wherein the second metal layer comprises a plurality of first signal wires located in the bezel region, the plurality of first signal wires of the at least one second metal layer comprises first trace portions extending in a first direction, the first direction intersects an extension direction of the barrier dams in the bezel region located on a same side as the first trace portions, an orthographic projection of the first trace portion on the base substrate spans an overlapping region of the orthographic projection of the first groove and the orthographic projection of the second groove, and in a same second metal layer, a ratio of a line distance between two adjacent first trace portions to a line width of the first trace portion is greater than or equal to 1 and less than or equal to 4.

2. The display substrate according to claim 1, wherein the at least one second metal layer comprises a bridge metal layer, and a touch electrode layer located at a side of the bridge metal layer away from the layer where the barrier dams are located, and a second insulation layer is arranged between the bridge metal layer and the touch electrode layer.

3. The display substrate according to claim 2, wherein at least some of the first trace portions are only located at the touch electrode layer; or,
wherein all the first trace portions are only located at the touch electrode layer.

4. (canceled)

5. The display substrate according to claim 3, wherein the bridge metal layer and the touch electrode layer both comprise the first trace portions, the first trace portions of the bridge metal layer and the first trace portions of the touch electrode layer are alternately arranged in a second direction, and the second direction is an extension direction of the barrier dams in the bezel region located on a same side as the first trace portions.

6. The display substrate according to claim 2, wherein at least some of the first trace portions are only located at the bridge metal layer; or,
wherein all the first trace portions are only located at the bridge metal layer.

7. (canceled)

8. The display substrate according to claim 6, wherein the bridge metal layer and the touch electrode layer both comprise the first trace portions, and the first trace portions of the bridge metal layer are electrically connected with the first trace portions of the touch electrode layer in a one-to-one correspondence manner.

9. The display substrate according to claim 2, wherein the first signal wires further comprise second trace portions in the bezel region, the second trace portions are electrically connected with the first trace portions, and orthographic projections of the second trace portions on the base substrate are located at a side of orthographic projections of the at least two barrier dams on the base substrate away from the display region; and,
wherein the second trace portions are located at the bridge metal layer and the touch electrode layer, the second insulation layer comprises a plurality of first via holes, and the second trace portions of the bridge metal layer are electrically connected with the second trace portions of the touch electrode layer in a one-to-one correspondence manner through the plurality of first via holes.

10. (canceled)

11. The display substrate according to claim 9, wherein the first signal wires further comprise third trace portions in the bezel region, the third trace portions are electrically connected with the first trace portions, and orthographic projections of the third trace portions on the base substrate are located at a side of the orthographic projections of the at least two barrier dams on the base substrate close to the display region.

12. The display substrate according to claim 11, wherein the third trace portions are located at the bridge metal layer and the touch electrode layer, the second insulation layer comprises a plurality of second via holes, and the third trace portions of the bridge metal layer are electrically connected with the third trace portions of the touch electrode layer in a one-to-one correspondence manner through the plurality of second via holes.

13. The display substrate according to claim 1, wherein the bridge metal layer and the touch electrode layer each comprise grounding wires located in the bezel region, and the grounding wires are located at a side of the plurality of first signal wires away from the display region;
at least some of the grounding wires comprise grounding portions arranged on a same layer as the first trace portions side by side, and a length of the grounding portion in the first direction is substantially the same as a length of the first trace portion in the first direction; and
the second insulation layer comprises a plurality of third via holes, and outside the grounding portions, the grounding wires of the touch electrode layer are electrically connected with the grounding wires of the bridge metal layer through of the plurality of third via holes.

14. The display substrate according to claim 1, wherein the bridge metal layer and the touch electrode layer each comprise a plurality of second signal wires located in the bezel region, each second signal wire comprises a fourth trace portion located in the bezel region, and an orthographic projection of the fourth trace portion on the base substrate is located between the orthographic projections of the at least two barrier dams on the base substrate and the display region.

15. The display substrate according to claim 14, wherein the second insulation layer comprises a plurality of fourth via holes, and the fourth trace portions of the bridge metal layer are electrically connected with the fourth trace portions of the touch electrode layer in a one-to-one correspondence manner through the plurality of fourth via holes.

16. The display substrate according to claim 14, wherein each second signal wire comprises a fifth trace portion extending in the first direction in the bezel region, the fifth trace portion and the fourth trace portion are integrally arranged, and an orthographic projection of the fifth trace portion on the base substrate spans the orthographic projections of the at least two barrier dams on the base substrate.

17. The display substrate according to claim 16, wherein each first metal layer further comprises a plurality of second leads located in the bezel region, and orthographic projections of the second leads of different first metal layers on the base substrate are staggered; a third groove is provided between two adjacent second leads of a same first metal layer, and orthographic projections of at least some of third grooves on the base substrate overlap the orthographic projections of the first grooves on the base substrate; and an orthographic projection of the fifth trace portion on the base substrate spans an overlapping region of the orthographic projection of the first groove and the orthographic projection of the third groove.

18. The display substrate according to claim 17, further comprising a plurality of data signal wires located between the at least two first metal layers and the layer where the barrier dams are located in the display region, and the plurality of data signal wires are electrically connected with the plurality of second leads.

19. The display substrate according to claim 1, wherein the first trace portion comprises a first trace sub-portion and a second trace sub-portion arranged integrally, an orthographic projection of the first trace sub-portion on the base substrate is located within the orthographic projections of the barrier dams on the base substrate, an orthographic projection of the second trace sub-portion on the base substrate does not overlap the orthographic projections of the barrier dams on the base substrate, and a line width of the first trace sub-portion is less than a line width of the second trace sub-portion.

20. The display substrate according to claim 19, wherein the line width of the first trace portion is greater than or equal to 8 μm and less than or equal to 15 μm, and the line distance between two adjacent first trace portions in the same second metal layer is greater than or equal to 15 μm and less than or equal to 30 μm; and,
wherein in the first direction, a distance between an edge of the orthographic projection of the first trace portion on the base substrate and an edge of the orthographic projections of the at least two barrier dams on the base substrate is greater than or equal to 40 μm and less than or equal to 60 μm, and the edge of the orthographic projection of the first trace portion and the edge of the orthographic projections of the at least two barrier dams are on a same side.

21. (canceled)

22. The display substrate according to claim 1, wherein the plurality of first signal wires comprise a plurality of touch signal wires, and guard lines on a side of the touch signal wires away from the display region.

23. The display substrate according to claim 1, further comprising a gate drive circuit located in the bezel region, wherein the gate drive circuit is electrically connected with the plurality of first leads.

24. A display device, comprising the display substrate of claim 1.
